(19) United States
(12) Patent Application Publication
(10) Pub. No.: US 2015/0179922 A1
(43) Pub. Date: Jun. 25, 2015

(54) TWO-DIMENSIONAL ZINC-OXIDE NANOSHEET-BASED POWER GENERATION DEVICE AND METHOD OF FABRICATING THE SAME

(71) Applicant: RESEARCH & BUSINESS FOUNDATION SUNGKYUNKAWAN UNIVERSITY, Suwon-si (KR)

(72) Inventors: Sang Woo Kim, Suwon-si (KR); Kown Ho Kim, Suwon-si (KR); Ju Hyuck Lee, Suwon-si (KR); Keun Young Lee, Suwon-si (KR); Wan Chul Seung, Yongin-si (KR)

(73) Assignee: RESEARCH & BUSINESS FOUNDATION SUNGKYUNKWAN UNIVERSITY, Suwon-si (KR)

(21) Appl. No.: 14/367,540

(22) PCT Filed: Dec. 20, 2012
(86) PCT No.: PCT/KR2012/011189

§ 371 Date: Jun. 20, 2014

(30) Foreign Application Priority Data
Dec. 23, 2011 (KR) 10-2011-0141104

(51) Int. Cl. H01L 41/187; H01L 41/317; H01L 41/113

(52) U.S. Cl. CPC H01L 41/187; H01L 41/1138; H01L 41/317

(57) ABSTRACT

The present invention relates to a two-dimensional zinc-oxide nanosheet-based piezoelectric power generation device. More specifically, the present invention relates to a piezoelectric power generation device using a two-dimensional zinc-oxide nanosheet to provide high mechanical reliability and high output power.

### CROSS REFERENCE TO RELATED APPLICATIONS

This application is a National Stage of International Application No. PCT/KR2012/011189 filed Dec. 20, 2012, claiming priority based on Korean Patent Application No. 10-2011-0141104 filed Dec. 23, 2011, the contents of all of which are incorporated herein by reference in their entirety.

### FIELD OF THE INVENTION

The present invention relates to a two-dimensional zinc-oxide nanosheet-based piezoelectric power generation device. More specifically, the present invention relates to a piezoelectric power generation device using a two-dimensional zinc-oxide nanosheet to provide high mechanical reliability and high output power.

The present invention is based on the result of a project: “Large-Scale Energy Harvesting Based on Piezoelectric Nanogenerators” (Total research period: May 1, 2010 to Apr. 30, 2013, Concerned year research period: May 1, 2011 to Apr. 30, 2012, Managing department name: National Research Foundation of Korea (NRF), Ministry name: Ministry of Education and Science Technology (MEST), Project No. 2010-0000297) 50%, a project: “Development of Monolithic Flexible Energy Harvesting Devices via Nanostructure Control” (Total research period: May 1, 2009 to Apr. 30, 2012, Concerned year research period: May 1, 2011 to Apr. 30, 2012, Managing department name: National Research Foundation of Korea (NRF), Ministry name: Ministry of Education and Science Technology (MEST), Project No. 2009-0077682) 40%, and a project: “Study on Shape-Convertible Information Input Sensor” (Total research period: Sep. 1, 2009 to Feb. 29, 2016, Concerned year research period: Mar. 1, 2011 to Feb. 28, 2012, Managing department name: National Research Foundation of Korea (NRF), Ministry name: Ministry of Education and Science Technology (MEST), Project No. 2009-0006273) 10%.

### DISCUSSION OF RELATED ART

Recently, a piezoelectric power generation device using a one-dimensional zinc-oxide nanorod disposed on a flexible polymer substrate has been developed.

The piezoelectric power generation device using the one-dimensional zinc-oxide nanorod is disclosed in Korean Patent No. 10-0851499. The piezoelectric power generation device using the one-dimensional zinc-oxide nanorod can be mass-produced, but is vulnerable to a large mechanical force and has low output power.

Accordingly, a piezoelectric power generation device that overcomes poor mechanical properties and has high output power has been required. The present invention provides a piezoelectric power generation device that solves those problems.

### DETAILED DESCRIPTION OF THE INVENTION

### Purpose of the Invention

The present invention is directed to a piezoelectric power generation device using a piezoelectric material which converts physical energy to electrical energy, and is also directed to a piezoelectric power generation device using a two-dimensional zinc-oxide nanosheet to provide high mechanical reliability and high output power.

### Means of the Invention

One aspect of the present invention provides a method of fabricating a two-dimensional zinc-oxide nanosheet-based piezoelectric power generation device including providing a substrate, such as plastic, paper, and glass, having aluminum deposited on a surface thereof or having an aluminum foil attached on a surface thereof, wet-growing a zinc-oxide nanosheet on the surface of the substrate having aluminum deposited thereon or having an aluminum foil attached thereon, providing a substrate, such as plastic, paper, and glass, having an electrode, such as gold (Au), platinum (Pt), palladium (Pd), Pd—Au alloy, nickel (Ni), Ni—Au alloy, ruthenium (Ru), silver (Ag), copper (Cu), zinc (Zn), titanium (Ti), Ti—Au alloy, aluminum (Al), indium tin oxide (ITO), fluorine-doped tin oxide (FTO), gallium-doped zinc-oxide (GZO), carbon nanotube (CNT), and graphene, deposited and transferred on a surface thereof, and attaching the substrate, such as plastic, paper, and glass, on which at least one of the above-described electrode materials is deposited or transferred, on the zinc-oxide nanosheet.

In some embodiments, the wet-growing of the zinc-oxide nanosheet may include forming a growth solution by dissolving zinc nitrate hexahydrate (Zn(NO₃)₂6H₂O) and hexamethylenetetramine (C₆H₁₂N₄) in deionized water, or zinc nitrate hexahydrate (Zn(NO₃)₂6H₂O) and aluminum nitrate nonahydrate (Al(NO₃)₃9H₂O) in deionized water, and growing the zinc-oxide nanosheet by immersing the plastic substrate having aluminum attached on the surface thereof in the growth solution. In this case, NaOH and HNO₃ may be used to control pH while forming the growth solution.

In other embodiments, the growing of the zinc-oxide nanosheet by immersing the substrate, such as plastic, paper, and glass, having aluminum deposited on the surface thereof or having aluminum foil attached on the surface thereof in the growth solution is performed for three hours at about 95° C. and 1 atm.

Another aspect of the present invention provides a two-dimensional zinc-oxide nanosheet-based piezoelectric power generation device including a substrate, such as plastic, paper, and glass, having aluminum deposited on a surface thereof or having an aluminum foil attached on a surface thereof, a zinc-oxide nanosheet wet-grown on the surface of the substrate having aluminum deposited thereon or having an aluminum foil attached thereon, and a plastic substrate having gold deposited on a surface thereof and arranged in such a way that the surface on which gold is deposited is in contact with the zinc-oxide nanosheet.

### Effect of the Invention

The present invention has an advantage that it can provide a piezoelectric power generation device supplementing a vulnerable mechanical property of the one-dimensional zinc-oxide nanorod and having high output power; thus it can provide mechanical reliability and high output power.

### BRIEF DESCRIPTION OF THE DRAWINGS

The above and other objects, features, and advantages of the present invention will become more apparent to those of ordinary skill in the art by describing in detail exemplary embodiments thereof with reference to the accompanying drawings, in which:

FIG. 1 is a process flowchart showing a method of fabricating a two-dimensional zinc-oxide nanosheet-based piezoelectric power generation device according to an embodiment of the present invention;

FIG. 2 is a schematic view showing a plastic substrate to which aluminum (Al) is attached;

FIG. 3A is a schematic view of a zinc-oxide nanosheet grown on a substrate, and FIG. 3B is an image showing an actual surface of a grown zinc-oxide nanosheet;

FIG. 4 is a schematic view showing a plastic substrate on which gold (Au) is deposited;

FIG. 5 is a schematic diagram showing a two-dimensional zinc-oxide nanosheet-based piezoelectric power generation device according to an embodiment of the present invention; and

FIGS. 6A to 6D are graphs showing mechanical reliabilities and outputs of a nanorod-based piezoelectric power generation device and a nanosheet-based piezoelectric power generation device, and SEM photographs of the nanorod-based piezoelectric power generation device and the nanosheet-based piezoelectric power generation device.

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it will be apparent to those skilled in the art that various modifications can be made without departing from the spirit and scope of the invention.

All terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

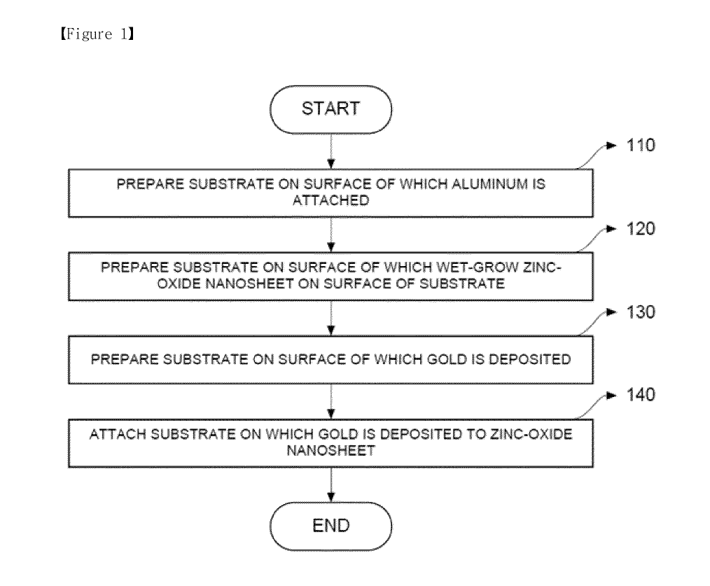

FIG. 1 is a process flowchart showing a method of fabricating a two-dimensional zinc-oxide nanosheet-based piezoelectric power generation device according to an embodiment of the present invention.

First, a substrate having aluminum attached on a surface thereof is provided (step 110), a zinc-oxide nanosheet is wet-grown on the surface of the substrate having aluminum attached thereon (step 120), a substrate having an electrode deposited on a surface thereof is provided (step 130), and the substrate on which the electrode is deposited is attached on the zinc-oxide nanosheet in such a way that the surface on which the electrode is deposited is in contact with the zinc-oxide nanosheet (step 140). Hereinafter, the method will be described step by step in detail.

(1) A Process of Providing a Substrate Having Aluminum Attached on a Surface Thereof (Step 110)

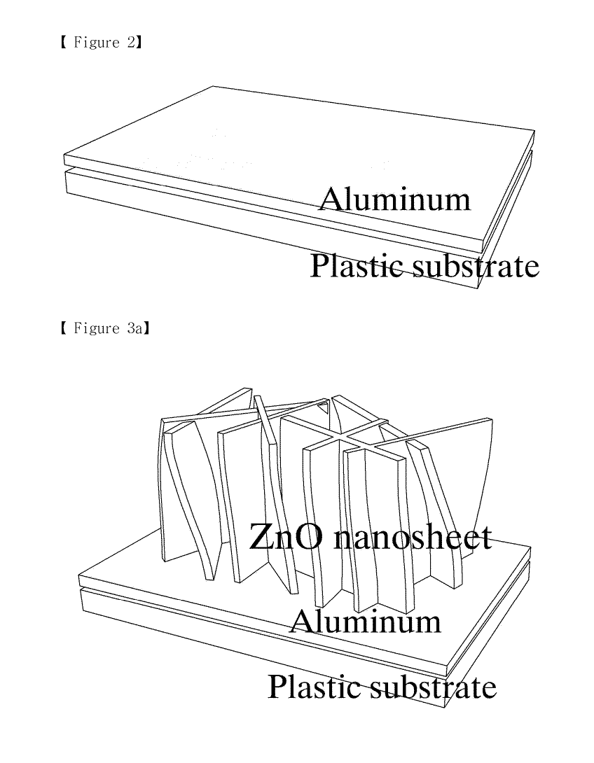

A substrate on which a ZnO nanosheet is to be grown is prepared by depositing or attaching an aluminum foil on a substrate as shown in FIG. 2. In this case, the substrate may be formed of at least one of plastic, paper, glass, and sapphire.

(2) A Process of Wet-Growing a Zinc-Oxide Nanosheet (Step 120)

A zinc-oxide nanosheet is wet-grown on the surface of the substrate having aluminum attached thereon. The substrate on which aluminum is attached has been prepared at the step 110.

In this case, the process of wet-growing the zinc-oxide nanosheet includes preparing a growth solution by dissolving zinc nitrate hexahydrate (Zn(NO₃)₂6H₂O) and hexamethylenetetramine (C₆H₁₂N₄) in deionized water, or zinc nitrate hexahydrate (Zn(NO₃)₂6H₂O) and aluminum nitrate nonahydrate (Al(NO₃)₃9H₂O) in deionized water, and growing the zinc-oxide nanosheet by immersing the substrate having aluminum attached on the surface thereof in the growth solution.

In this case, NaOH and HNO₃ may be used to control pH.

For example, the growth solution is prepared by dissolving Zn(NO₃)₂6H₂O (1.86 g) and C₆H₁₂N₄ (0.87 g) in DI-water (250 mL), and growing the zinc-oxide nanosheet by immersing the prepared substrate having the aluminum attached on the surface thereof in the growth solution for three hours at about 95° C. and 1 atm.

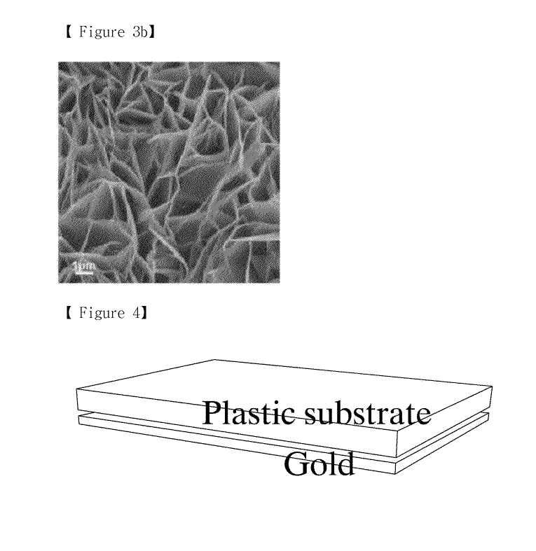

FIG. 3A is a schematic view of a zinc-oxide nanosheet grown on a substrate, and FIG. 3B is an image showing an actual surface of the grown zinc-oxide nanosheet.

(3) A Process of Providing a Substrate on which an Electrode is Deposited (Step 130)

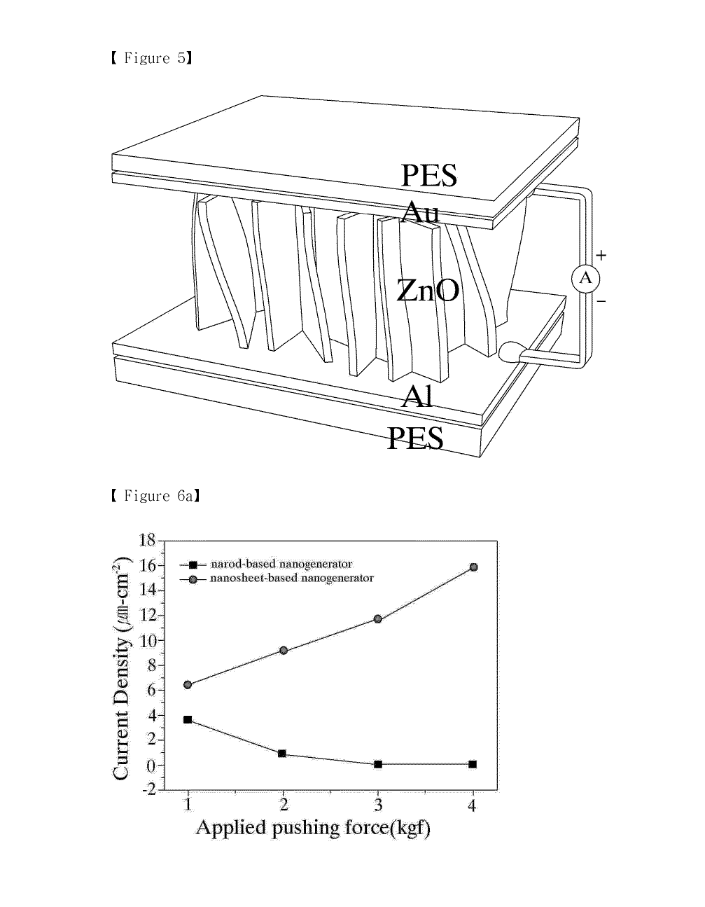

In order to fabricate a nanosheet-based piezoelectric power generation device, gold is deposited in a thickness of 100 nm on a flexible plastic substrate using a thermal evaporator, as shown in FIG. 4. Gold may be used as an electrode of the piezoelectric power generation device.

In this case, the substrate may be formed of at least one of plastic, paper, glass, and sapphire.

The electrode may be formed of at least one of gold (Au), platinum (Pt), palladium (Pd), Pd—Au alloy, nickel (Ni), Ni—Au alloy, ruthenium (Ru), silver (Ag), copper (Cu), zinc (Zn), titanium (Ti), Ti—Au alloy, aluminum (Al), indium tin oxide (ITO), fluorine-doped tin-oxide (FTO), gallium-doped zinc-oxide (GZO), carbon nanotube (CNT), and graphene.

(4) A Process of Attaching the Substrate Having the Electrode Deposited Thereon on the Zinc-Oxide Nanosheet (Step 140)

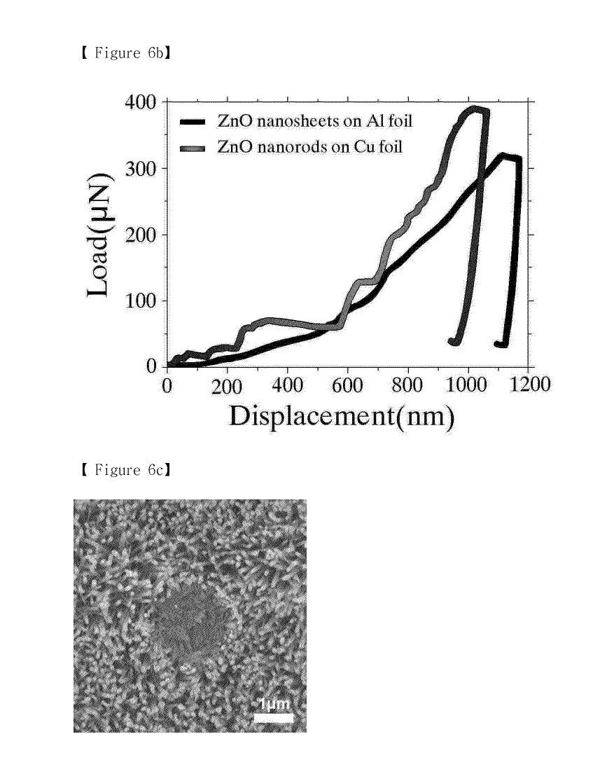

A nanosheet-based piezoelectric power generation device is formed by physically attaching the substrate having gold deposited thereon, which is prepared in the step 130, on the nanosheet of FIG. 3A in such a way that a surface on which gold is deposited is in contact with the nanosheet. Next, a conducting wire is connected to the gold, i.e. an upper electrode and the aluminum, i.e. a lower electrode using a silver paste, etc., as shown in FIG. 5.

FIG. 5 is a schematic diagram showing a two-dimensional zinc-oxide nanosheet-based piezoelectric power generation device according to an embodiment of the present invention.

The zinc-oxide nanosheet-based piezoelectric power generation device according to the embodiment of the present invention may be grown in a wet environment. In addition, the zinc-oxide nanosheet according to the embodiment of the present invention has a networked structure as shown in FIG. 3B, and thereby endure much more mechanical energy compared to a zinc-oxide nanorod having a one-dimensional structure.

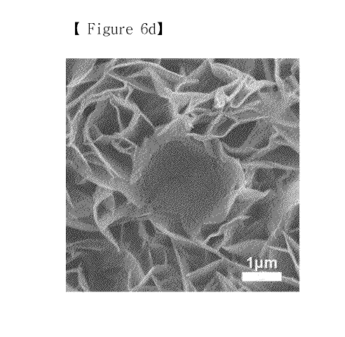

In addition, the two-dimensional zinc-oxide nanosheet-based piezoelectric power generation device according to the embodiment of the present invention shows about three to four times as high output voltage and output current density as an existing one-dimensional zinc-oxide nanorod-based piezoelectric power generation device, which can be shown in FIG. 6A.

As shown in FIG. 6A, the two-dimensional zinc-oxide nanosheet-based piezoelectric power generation device according to the embodiment of the present invention shows high output power even in a low force (1 kgf), and the current density continually increases as the applied force increases. However, the current density continually decreases as the applied force increases in the nanorod-based piezoelectric power generation device, which is because the nanorod does not endure a mechanical force and becomes broken as the applied force increases.

FIG. 6B is a graph showing data in which mechanical properties of the nanorod and the nanosheet are analyzed. In FIG. 6B, arrows point deformation critical loads of the nanorod and the nanosheet. When a load exceeds the critical load, the nanorod is broken and the nanosheet is not broken and has deformation enough to support each other due to the networked structure. FIG. 6C shows an FE-SEM photograph in which the nanorod is broken, and FIG. 6D shows an FE-SEM photograph in which the nanosheet has deformation but is not broken.

Table 1 shows the results calculated based on data of FIGS. 6A and 6B. In Table 1, since the nanorod has a high elastic modulus but has a lower strain energy compared to the nanosheet, the nanorod may be easily broken.

TABLE 1

| | Nanosheet | Nanorod |
|---|---|---|
| Critical Loads (N) | 5.56E−5 | 1.17E−4 |
| Length (m) | 3.00E−6 | 2.00E−6 |
| Area (m²) | 3.83E−14 | 5.02E−13 |
| Strain Energy (J) | 9.50E−12 | 8.05E−12 |
| Strain Energy Density (J/m³) | 7.90E+7 | 7.50E+6 |
| Elastic Modulus; Young's Modulus (Pa) | 1.35E+10 | 1.18E+11 |

The two-dimensional zinc-oxide nanosheet-based piezoelectric power generation device according to the embodiment of the present invention is mechanically stable and generates high output power by remedying weak mechanical properties of one-dimensional zinc-oxide nanorod.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

1. A method of fabricating a two-dimensional zinc-oxide nanosheet-based power generation device, comprising:
providing a substrate having aluminum attached on a surface thereof;
wet-growing a zinc-oxide nanosheet on the surface of the substrate having aluminum attached thereon;
providing a substrate having an electrode attached on a surface thereof; and
attaching the substrate on which the electrode is deposited on the zinc-oxide nanosheet in such a way that the surface on which the electrode is deposited is in contact with the zinc-oxide nanosheet.

2. The method of claim 1, wherein the wet-growing of the zinc-oxide nanosheet comprises:
forming a growth solution by dissolving zinc nitrate hexahydrate (Zn(NO₃)₂6H₂O) and hexamethylenetetramine (C₆H₁₂N₄) in deionized water, or zinc nitrate hexahydrate (Zn(NO₃)₂6H₂O) and aluminum nitrate nonahydrate (Al(NO₃)₃9H₂O) in deionized water; and
growing the zinc-oxide nanosheet by immersing the substrate having aluminum attached on the surface thereof in the growth solution.

3. The method of claim 2, wherein the forming of the growth solution uses NaOH and HNO₃ to control pH.

4. The method of claim 2, wherein the growing of the zinc-oxide nanosheet by immersing the substrate having aluminum attached on the surface thereof in the growth solution is performed at about 95° C. and about 1 atm for three hours.

5. The method of claim 1, wherein the substrate is formed of at least one of plastic, paper, glass, and sapphire, and
the electrode is formed of at least one of gold (Au), platinum (Pt), palladium (Pd), Pd—Au alloy, nickel (Ni), Ni—Au alloy, ruthenium (Ru), silver (Ag), copper (Cu), zinc (Zn), titanium (Ti), Ti—Au alloy, aluminum (Al), indium tin oxide (ITO), fluorine-doped tin-oxide (FTO), gallium-doped zinc-oxide (GZO), carbon nanotube (CNT), and graphene.

6. A method of fabricating a two-dimensional zinc-oxide nanosheet-based power generation device, comprising:
providing a plastic substrate having aluminum attached on a surface thereof;
wet-growing a zinc-oxide nanosheet on the surface of the substrate having aluminum attached thereon, wherein the growing the zinc-oxide nanosheet includes forming a growth solution by dissolving zinc nitrate hexahydrate (Zn(NO₃)₂6H₂O) and hexamethylenetetramine (C₆H₁₂N₄) in deionized water and growing the zinc-oxide nanosheet by immersing the plastic substrate having aluminum attached on the surface thereof in the growth solution for three hours at about 95° C. and 1 atm;
providing a plastic substrate having Au attached on a surface thereof; and
attaching the substrate on which Au is deposited on the zinc-oxide nanosheet in such a way that the surface on which Au is deposited is in contact with the zinc-oxide nanosheet.

7. A two-dimensional zinc-oxide nanosheet-based power generation device, comprising:
a substrate having aluminum attached on a surface thereof;
a zinc-oxide nanosheet wet-grown on the surface of the substrate having aluminum attached thereon; and
a substrate having an electrode deposited on a surface thereof and arranged in such a way that the surface on which the electrode is deposited is in contact with the zinc-oxide nanosheet.

8. The two-dimensional zinc-oxide nanosheet-based power generation device of claim 7, wherein the zinc-oxide nanosheet is wet-grown by forming a growth solution by dissolving zinc nitrate hexahydrate (Zn(NO₃)₂6H₂O) and hexamethylenetetramine (C₆H₁₂N₄) in deionized water, or zinc nitrate hexahydrate (Zn(NO₃)₂6H₂O) and aluminum nitrate nonahydrate (Al(NO₃)₃9H₂O) in deionized water, and growing the zinc-oxide nanosheet by immersing the substrate having aluminum attached on the surface thereof in the growth solution.

9. The two-dimensional zinc-oxide nanosheet-based power generation device of claim 8, wherein the forming of the growth solution uses NaOH and HNO₃ to control pH.

10. The two-dimensional zinc-oxide nanosheet-based power generation device of claim 8, wherein the growing of the zinc-oxide nanosheet by immersing the substrate having aluminum attached on the surface thereof in the growth solution is performed for three hours at about 95° C. and 1 atm.

11. The two-dimensional zinc-oxide nanosheet-based power generation device of claim 7, wherein the substrate is formed of at least one of plastic, paper, glass, and sapphire, and
the electrode is formed of at least one of gold (Au), platinum (Pt), palladium (Pd), Pd—Au alloy, nickel (Ni), Ni—Au alloy, ruthenium (Ru), silver (Ag), copper (Cu), zinc (Zn), titanium (Ti), Ti—Au alloy, aluminum (Al), indium tin oxide (ITO), fluorine-doped tin-oxide (FTO), gallium-doped zinc-oxide (GZO), carbon nanotube (CNT), and graphene.
